(19) United States
(12) Patent Application Publication
(10) Pub. No.: US 2009/0007961 A1
(43) Pub. Date: Jan. 8, 2009

(54) Photoelectric Converter and Semiconductor Electrode

(75) Inventor: Masahiro Morooka, Kanagawa (JP)

Correspondence Address: WOLF GREENFIELD & SACKS, P.C., 600 ATLANTIC AVENUE, BOSTON, MA, 02210-2206, US

(73) Assignee: SONY CORPORATION, Tokyo (JP)

(21) Appl. No.: 11/596,094

(22) PCT Filed: Mar. 31, 2005
(86) PCT No.: PCT/JP2005/006813

§ 371 Date: Aug. 8, 2008

(30) Foreign Application Priority Data
May 13, 2004 (JP) 2004-142990

(51) Int. Cl. H01L 31/00

(52) U.S. Cl. 136/256

(57) ABSTRACT

Disclosed herein is a photoelectric converter which has an improved photoelectric conversion efficiency and an improved current density owing to the increased amount of sensitizing dye supported on the semiconductor electrode. The photoelectric converter (1) is comprised of a semiconductor electrode (11), a counter electrode (12), and an electrolyte layer (5) held between them. The semiconductor electrode (11) is comprised of a transparent substrate (2) and a layer of fine semiconductor fine particles (4). The photoelectric converter (1) is characterized in that the layer of fine semiconductor fine particles (4) undergoes hydrothermal treatment so that the semiconductor fine particles have an increased specific surface area and hence an increased amount of sensitizing dye supported thereon.

### TECHNICAL FIELD

The present invention relates to a photoelectric converter and a semiconductor electrode suitable therefor.

### BACKGROUND ART

It is said that fossil fuel (such as coal and petroleum) as an energy source emits carbon dioxide which results in global warming.

It is feared that nuclear power might cause contamination with radiation.

The global and local environmental problems will become more serious if man continues to depend on the conventional energies for their living and economic activity.

Utilizing sunlight as an energy source is realized by using solar cells which are photoelectric converters to convert sunlight into electric energy. Solar cells have very little influence on the global environment and their wide spread is expected.

Most commercial solar cells are made with silicon, which is classified into single crystal silicon, polycrystalline silicon, and amorphous silicon.

Conventional solar cells are usually made with single crystal silicon or polycrystalline silicon.

Solar cells based on crystalline silicon are superior to solar cells based on amorphous silicon in conversion efficiency (which denotes the ability of solar cells to convert light energy (or solar energy) into electric energy). However, crystalline silicon needs a large amount of energy and time for crystal growth, which leads to low productivity and economical disadvantage.

On the other hand, solar cells based on amorphous silicon are inferior in conversion efficiency to solar cells based on crystalline silicon; however, the former have an advantage over the latter because of the high light absorptivity, the extensive choice of substrates, and the easy availability of large substrates. In addition, the former are superior in productivity to the latter; however, this advantage is offset by the necessity of expensive facilities for vacuum process.

For the purpose of reducing production cost further, extensive studies have been made on solar cells based on organic materials in place of silicon. Such solar cells, however, have a very low photoelectric conversion efficiency (less than 1%) and are poor in durability.

Under these circumstances, there has been reported a new, inexpensive solar cell which has an improved photoelectric conversion efficiency owing to dye-sensitized porous semiconductor fine particles. (See Nature, 353, p. 737-740, (1991), for example.)

This solar cell is that of wet type or an electrochemical photocell in which the photoelectrode is formed from a porous thin film of titanium oxide sensitized (for specific wavelength) with a ruthenium complex as a sensitizing dye.

This solar cell offers the advantage of being produced from an inexpensive oxide semiconductor (such as titanium oxide), containing a sensitizing dye capable of absorbing visible rays over a broad range of wavelength up to 800 nm, and having a high quantum efficiency for photoelectric conversion (or a high energy conversion efficiency). Another advantage is that there is no need for vacuum process and large facilities therefor.

For a dye-sensitized solar cell to improve in efficiency, it should have a dye (which absorbs light for conversion into electrons) densely supported on a semiconductor electrode.

According to the technique developed by Graetzel et al., the foregoing object is achieved by subjecting the semiconductor fine particles (constituting the semiconductor electrode) to sintering, thereby increasing their specific surface area. This technique, however, does not increase the amount of the supported sensitizing dye as much as desired. It merely gives a semiconductor electrode which is unsuitable for future photoelectric converters requiring a much higher efficiency.

It is an object of the present invention to provide a new semiconductor electrode that supports more sensitizing dye than before and permits improvement in photoelectric conversion efficiency and current density. It is another object of the present invention to provide a photoelectric converter which is provided with said semiconductor electrode.

### DISCLOSURE OF THE INVENTION

The present invention is directed to a photoelectric converter of the type having a transparent substrate, at least a semiconductor electrode formed thereon which is a layer of semiconductor fine particles, a counter electrode, and an electrolyte layer held between said semiconductor electrode and said counter electrode, wherein said layer of semiconductor fine particles is one which is prepared by forming a film from semiconductor fine particles on said transparent substrate and subsequently subjecting the resulting film to hydrothermal treatment in an environment of pH 10 or higher, so that the semiconductor fine particles have an increased specific surface area.

The semiconductor electrode according to the present invention is composed of a transparent substrate and at least a layer of semiconductor fine particles formed thereon. The layer of semiconductor fine particles, which has been formed on the transparent substrate, undergoes hydrothermal treatment, so that the semiconductor fine particles have an increased specific surface area.

According to the present invention, the layer of semiconductor fine particles constituting the semiconductor electrode undergoes hydrothermal treatment, so that the semiconductor fine particles have an increased specific surface area. The increased specific surface area permits the sensitizing dye to be supported more than before. Thus the resulting photoelectric converter has an improved photoelectric converting efficiency and an increased current density.

### BRIEF DESCRIPTION OF THE DRAWING

FIG. 1 is a schematic diagram showing the structure of the photoelectric converter according to the present invention.

### BEST MODE FOR CARRYING OUT THE INVENTION

The invention will be described in more detail with reference to the following embodiments in conjunction with the accompanying drawings, which are not intended to restrict the scope thereof.

The following is concerned mainly with the photoelectric converter; however, it is concerned also with the semiconductor electrode as a constituent thereof.

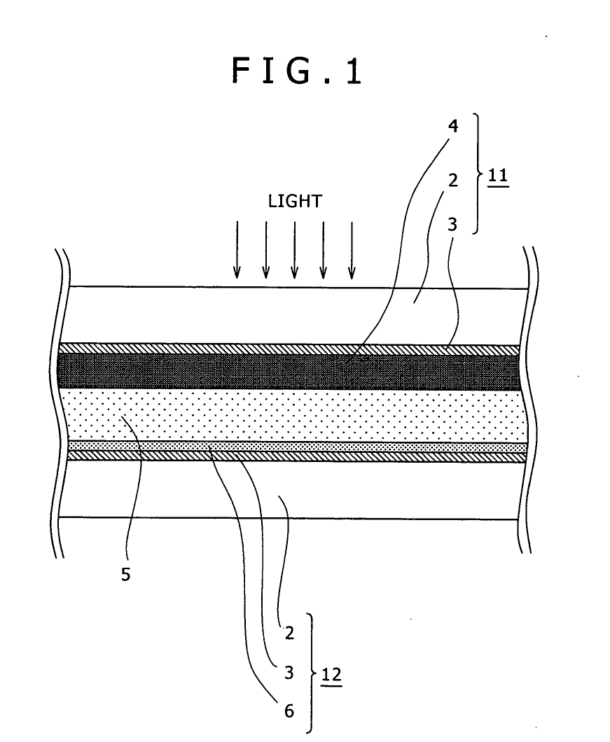

FIG. 1 is a schematic diagram showing the structure of one example of the photoelectric converter 1 according to the present invention.

The photoelectric converter 1 is comprised of a semiconductor electrode 11, a counter electrode 12, and an electrolyte layer 5 held between the two electrodes 11 and 12. The semiconductor electrode 11 is composed of a transparent substrate 2, a transparent conducting layer 3, and a layer of semiconductor fine particles 4. The counter electrode 12 is composed of a transparent substrate 2, a transparent conducting layer 3, and a platinum layer 6 treated with chloroplatinic acid.

The photoelectric converter 1 is designed such that light impinges on the semiconductor electrode 11.

A description of the semiconductor electrode 11 follows.

The transparent substrate 2 is not specifically restricted; it may be one which is commonly used for semiconductor electrodes.

The transparent substrate 2 should preferably have good barrier properties, good solvent resistance, and good weather resistance. Barrier properties are necessary to protect the photoelectric converter 1 from moisture and gas. Preferred examples of the transparent substrate 2 include transparent inorganic substrates (made of quartz, sapphire, glass, or the like) and transparent plastic substrates (made of polyethylene terephthalate, polyethylene naphthalate, polycarbonate, polystyrene, polyethylene, polypropylene, polyphenylenesulfide, polyvinylidene fluoride, tetraacetyl cellulose, brominated phenoxy, aramid, polyimide, polystyrene, polyallylate, polysulfone, polyolefin, or the like). The transparent substrate 2 should preferably be made of a material having a high transmission of visible light.

A preferred material is one which has high resistance to alkaline aqueous solutions, because the manufacturing process according to the present invention involves hydrothermal treatment in an alkaline environment.

The transparent substrate 2 is not specifically restricted in thickness. An adequate thickness should be selected according to the light transmission required and the barrier properties required.

The transparent conducting layer 3 is made of a material which is transparent and electrically conductive. Preferred examples of such a material include zinc oxide (ZnO), tin oxide (SnO₂), indium oxide (In₂O₃), and solid solution of tin oxide and indium oxide (SnO₂—In₂O₃ or ITO).

ITO film is particularly desirable. It may be used alone or it may be doped with such an element as Zr, Hf, Te, and F. It may also be formed into a laminate with any other transparent conducting material. The laminate structure may consist of two layers of ITO and an intermediate layer of Au, Ag, Cu, or the like held between them. It may also consist of two oxide layers and an intermediate nitride layer held between them. It may also consist of more than two kinds of oxide layers. The photoelectric converter 1 according to the present invention may have any other laminate structure than mentioned above.

The transparent conducting layer 3 should preferably be one which has a low surface resistance, that is, lower than 500Ω/□, more desirably lower than 100Ω/□.

Examples of the materials meeting this requirement include indium-tin compound oxide (ITO), fluorine-doped tin oxide (FTO), and antimony-doped tin oxide (ATO). They may be used alone or in combination with one another.

The transparent conducting layer 3 may be combined with wiring of highly conductive metal or carbon for the purpose of reducing the surface resistance and improving the current collecting efficiency.

The layer of semiconductor fine particles 4 may be formed from semiconductor fine particles. The semiconductor may be silicon (in the form of simple substance) or a compound semiconductor or any compound having the perovskite structure.

These semiconductors should preferably be an n-type semiconductor in which conduction electrons excited by light function as carriers to produce the anode current.

Typical examples of such semiconductors include TiO₂, ZnO, WO₃, Nb₂O₅, TiSrO₅, and SnO₂. Preferable among these is TiO₂ of anatase type. They may be used alone or in combination with one another. The semiconductor fine particles may assume a granular, tubular, rodlike, or any other shape.

The photoelectric converter 1 causes a photoelectric chemical reaction to take place between the layer of semiconductor fine particles 4 and the electrolyte layer 5 (mentioned later). It is important to make provision for efficient charge transfer reactions at the interface between the two layers.

For this reason, the present invention involves hydrothermal treatment to be carried out after the layer of semiconductor fine particles 4 has been formed on the transparent substrate. The hydrothermal treatment increases the specific surface area of the semiconductor fine particles.

The semiconductor fine particles with an increased specific surface area provide more reaction sites for charge transfer, which in turn improves the photoelectric conversion efficiency.

The increased specific surface area produces another effect of increasing the diffusion of incident light. Diffused light permits more efficient use of light than undiffused light passing through a flat material.

The layer of semiconductor fine particles 4 may be formed by any method without specific restrictions. A wet process is desirable for low cost, easy handling, and good physical properties imparted to the layer. It consists of steps of evenly dispersing semiconductor fine particles (in the form of powder or sol) into an adequate solvent (such as water), thereby giving a paste, and applying the resulting paste to a substrate on which a transparent conducting film has been formed.

The method of application is not specifically restricted. It includes any known ones such as dipping, spraying, wire bar coating, spin coating, roller coating, blade coating, and gravure coating. It also includes such wet printing methods as relief printing, offset printing, gravure printing, intaglio printing, rubber plate printing, and screen printing. The same object as coating may be accomplished by electrolytic deposition in a sol solution containing semiconductor fine particles dispersed therein.

The semiconductor fine particles are not specifically restricted in particle diameter. A desirable average particle diameter (for primary particles) is 1 to 200 nm, particularly 5 to 100 nm.

The semiconductor fine particles may be incorporated with two or more kinds of additional particles differing in particle diameter. The resulting mixture of semiconductor fine particles diffuses the incident light to improve the quantum efficiency. The additional particles should have an average particle diameter of 20 to 500 nm.

If titanium oxide of anatase type is used for the layer of semiconductor fine particles 4, it may be in the form of powder, sol, or slurry. Titanium oxide (in the form of powder with a desired particle diameter) may also be obtained from titanium alkoxide by hydrolysis.

Titanium oxide in powder form should preferably be pulverized before use by means of a mortar or ball mill when it is made into a coating solution. This step is necessary to prevent agglomeration of particles. The pulverized powder should be incorporated with any of acetylacetone, hydrochloric acid, nitric acid, surface active agent, and chelating agent to prevent it from agglomerating again.

The coating solution may be incorporated with a thickener such as polyethylene oxide, polyvinyl alcohol, and cellulose derivative.

Application of semiconductor fine particles should preferably be followed by firing, which causes semiconductor fine particles to come into electronic contact with one another, thereby improving film strength and film adhesion.

Firing is not specifically restricted in temperature; an adequate firing temperature is 40 to 700° C., preferably 40 to 650° C. Firing at an excessively high temperature causes particles to melt or yields a layer of particles with a high resistance.

Firing is not specifically restricted in duration. It should be carried out for 10 minutes to 10 hours for practical purpose.

Firing may optionally be followed by post treatment to increase the specific surface area of semiconductor fine particles or to enhance necking between semiconductor fine particles. The post treatment includes chemical plating with an aqueous solution of titanium tetrachloride, electrochemical plating with an aqueous solution of titanium trichloride, and dipping in a sol of semiconductor fine particles having a particle diameter smaller than 10 nm.

In the case where the transparent substrate 2 is a plastic plate, the semiconductor fine particles may be bonded under pressure (by using a hot press) onto the substrate coated with a binder-containing paste.

The following is concerned with the hydrothermal treatment to increase the specific surface area of the layer of semiconductor fine particles 4.

The hydrothermal treatment should be carried out by using an alkaline aqueous solution with pH 10 or above, preferably pH 13 or above.

A preferred alkaline aqueous solution is one which contains at least one species selected from KOH, NaOH, LiOH, RbOH, Ca(OH)₂, Mg(OH)₂, Sr(OH)₂, Ba(OH)₂, Al(OH)₃, Fe(OH)₃, Cu(OH)₂, ammonium compound, and pyridinium compound. Those which contain KOH, NaOH, or LiOH are particularly desirable. Hydrothermal treatment with one of these alkaline aqueous solutions effectively increases the specific surface area of the layer of semiconductor fine particles 4.

The hydrothermal treatment may be accomplished at any temperature without specific restrictions. Higher temperatures are desirable for higher reaction rates. An adequate temperature is from 30° C. to 300° C., depending on productivity and apparatus.

The hydrothermal treatment is not specifically restricted in duration. Treatment lasting for 1 minute to 10 hours, preferably 10 minutes to 6 hours, is desirable for adequate productivity.

It is necessary to properly select, in consideration of productivity, the concentration of aqueous solution, the temperature of treatment, and the duration of treatment, which influence the effect of increasing the specific surface area of the layer of semiconductor fine particles.

The layer of semiconductor fine particles 4 should support a sensitizing dye (not shown) which increases the photoelectric conversion efficiency.

For the layer of semiconductor fine particles 4 to adsorb a larger amount of dye than usual, it should undergo the above-mentioned hydrothermal treatment which increases its specific surface area.

After the layer of semiconductor fine particles 4 has been formed, the semiconductor fine particles therein should have a surface area which is more than 10 times (preferably 100 times) their projected area. A ratio of 1000 times is considered maximum although there is no upper limit.

In general, the amount of the dye supported per unit projected area is proportional to the thickness of the layer of semiconductor fine particles 4. The increased dye content leads to an increase in light capture ratio. However, this merit is offset by the loss due to charge recombination which results from injected electrons increasing in diffusion length.

Therefore, the layer of semiconductor fine particles 4 should have a thickness of 0.1 to 100 μm, preferably 1 to 50 μm, more preferably 3 to 30 μm.

The layer of semiconductor fine particles 4 may support any sensitizing dye which is not specifically restricted. Examples of the sensitizing dye include xanthene dyes (such as Rhodamine B, rose bengal, eosin, and erythrosine), cyanine dye (such as merocyanine, quinocyanine, and criptocyanine), basic dye (such as phenosafranine, capri blue, thiocin, and methylene blue), porphyrin compound (such as chlorophyll, zinc porphyrin, and magnesium porphyrin), azo dye, phthalocyanine compound, coumarin compound, Ru pyridine complex compound, anthraquinone dye, and polycyclic quinone dye.

Of these examples, Ru pyridine complex compound is desirable because of its high quantum efficiency. The above-mentioned sensitizing dyes may be used alone or in combination with one another.

Any adequate method may be used to cause the sensitizing dye to adsorb to the layer of semiconductor fine partiales 4. A typical method consists of dipping the semiconductor electrode (on which is formed the layer of semiconductor fine particles) in a solvent solution of the sensitizing dye, or coating the layer of semiconductor fine particles with a solvent solution of the sensitizing dye. Examples of the solvent include alcohols, nitrites, nitro compounds (such as nitromethane), halogenated hydrocarbons, ethers, sulfoxides (such as dimethylsulfoxide), pyrrolidones (such as N-methypyrrolidone), ketones (such as 1,3-dimethylimidazolidinone and 3-methyloxazolidinone), esters, carbonate esters, hydrocarbons, and water.

The dye solution may be incorporated with deoxycholic acid (together with an optional UV absorber) to protect the dye from association.

The semiconductor fine particles to which the sensitizing dye has adsorbed as mentioned above may have its surface treated with an amine.

Examples of the amine include pyridine, 4-tert-butylpyridine, and polyvinylpyridine. An amine in liquid form may be used as such, and an amine in solid form may be used after dissolution in an organic solvent.

A description of the counter electrode 12 is given below.

The counter electrode 12 consists of a transparent substrate 2, a transparent conducing layer 3, and a platinum layer 6.

The construction of the counter electrode 12 may be changed as desired so long as the transparent layer faces the semiconductor electrode 11 mentioned above.

The transparent conducting layer 3 should preferably be formed from an electrochemically stable material, such as platinum, gold, carbon, and conducting polymer.

That side of the counter electrode 12 which faces the semiconductor electrode should preferably have a fine structure with a large surface area so that it effectively functions as a catalyst for oxidation-reduction reaction. Platinum on that side should preferably be in a state of platinum black, and carbon on that side should preferably be in a porous state.

Platinum in a state of platinum black may be formed by anodizing process or treatment with chloroplatinic acid. Carbon in a porous state may be formed by sintering carbon fine particles or firing an organic polymer.

The counter electrode 12 may be formed by making wiring from metal (such as platinum that functions as a catalyst for oxidation-reduction reaction) on the transparent conducting substrate or by forming the platinum layer 6 which has its surface treated with chloroplatinic acid.

The electrolyte 5 is formed from any known electrolyte solution containing at least one substance that reversibly undergoes the change of state between oxidation and reduction.

Examples of such a substance include a combination of I₂ and metal iodide (or organic iodide), a combination of Br₂ and metal bromide (or organic bromide), metal complex (such as ferrocyanate/ferricyanate and ferrocene/ferricinium ion), sulfur compound (such as polysodium sulfide and alkylthiol/alkyldisulfide), biologen dye, and hydroquinone/quinone.

The metal compound mentioned above should preferably have a cation such as Li, Na, K, Mg, Ca, and Cs. The organic compound mentioned above should preferably have a quaternary ammonium compound (such as tetraalkyl ammonium, pyridinium, and imidazolium) as a cation. They may be used alone or in combination with one another.

Preferable among these electrolyte is a combination of I₂ and LiI or NaI, or a combination of I₂ and a quaternary ammonium compound (such as imidazolium iodide).

The concentration of the electrolyte salt should be 0.05 to 5 M (based on the solvent), preferably 0.2 to 1 M.

The concentration of I₂ and Br₂ should be 0.0005 to 1 M, preferably 0.001 to 0.1 M.

The electrolyte may be incorporated with a variety of additives, such as 4-tert-butylpyridine and carboxylic acid, for desirable open-circuit voltage and short-circuit current.

The solvent for the electrolyte layer 5 may be selected, without specific restrictions, from water, alcohols, ethers, esters, carbonate esters, lactones, carboxylate esters, phosphate triesters, heterocyclic compounds, nitriles, ketones (such as 1,3-dimethylimidazolidinone and 3-methyloxazolidinone), pyrrolidones (such as N-methylpyrrolidone), nitro compounds (such as nitromethane), halogenated hydrocarbons, sulfoxides (such as dimethylsulfoxide), sulfolane, 3-methyloxazolidinone, and hydrocarbons. They may be used alone or in combination with one another.

Other examples of the solvent include ionic solutions (at room temperature) of quaternary ammonium salt (with tetraalkyl, pyridinium, or imidazolium).

The composition constituting the electrolyte layer may contain any of gelling agent, polymer, and polymerizable monomer (dissolved therein) so that it is used in a gel state. This reduces the leakage and evaporation of the electrolyte from the photoelectric converter 1.

The electrolyte composition should contain the gel matrix in an adequate amount. It has a high ionic conductivity but is poor in mechanical strength if its gel content is low.

Conversely, the electrolyte composition has a high mechanical strength but is poor in ionic conductivity if its gel content is high. An adequate amount of the electrolyte composition is 50 to 99 wt %, preferably 80 to 97 wt %, of the total amount.

The photoelectric converter may be obtained in a solid form if the electrolyte mentioned above is dissolved in a polymer with the help of a plasticizer and then removing the plasticizer by evaporation.

The photoelectric converter 1 constructed as mentioned above may be completed by sealing the entire body in plastics resin or by sealing individual elements in a case.

The photoelectric converter 1 may be prepared in any manner without specific restrictions. It is only necessary that the composition constituting the electrolyte layer 5 should be in the form of liquid or gel (after conversion in the photoelectric converter). The electrolyte composition in liquid form should be introduced into the space between the semiconductor electrode 11 (supporting the dye) and the counter electrode 12, which are held apart.

The gap between the semiconductor electrode 11 and the counter electrode 12 is not specifically restricted. It is usually 1 to 100 μm, preferably 1 to 50 μm. An excessively large gap leads to a low conductivity and hence a low photoelectric current.

Sealing may be accomplished in any manner without spe—cific restrictions. It is desirable to use a sealing material having adequate light fastness, insulating properties, and moisture resistance. Typical examples of the sealing material include epoxy resin, UV-curable resin, acrylic resin, EVA (ethylene vinyl acetate), ionomer resin, ceramics, and heat adhesive film.

The solution of the electrolyte composition is introduced into the gap (cell) between the two electrodes through an inlet which is away from either of the two electrodes.

Introduction into the cell may be accomplished in any manner without specific restrictions. The solution may be introduced into the previously sealed cell through a port.

In practice, the port is filled with a few drops of solution and the solution is allowed to enter the cell by capillary action.

Introduction of the solution may be accelerated by heating or evacuation.

After the solution has been introduced completely, the port is cleared of the residual solution and then sealed. This sealing may be accomplished in any manner without specific restrictions. If necessary, the port may be sealed by attaching a glass plate or plastic plate with an adhesive.

A different method than above is used for the polymerbased gel-like electrolyte or the solid electrolyte. This method consists of casting a polymer solution containing an electrolyte and a plasticizer onto the semiconductor electrode supporting the sensitizing dye.

After the plasticizer has been removed completely, the electrolyte is sealed in the same way as mentioned above.

Sealing should preferably be accomplished by using a vacuum sealer in an atmosphere of inert gas or reduced pressure. After sealing, the entire assembly may optionally be heated or pressed to ensure that the electrolyte infiltrates completely into the layer of semiconductor fine particles.

Incidentally, the photoelectric converter 1 may take on various shapes depending on its application. Its shape is not specifically restricted.

The photoelectric converter 1 works in the following way.

For the photoelectric converter 1 to generate electricity, it is exposed to sunlight. The incident light through the transparent substrate 2 (as the constituent of the semiconductor electrode 11) excites the sensitizing dye supported on the surface of the layer of semiconductor fine particles 4. The excited sensitizing dye rapidly transfers electrons to the layer of semiconductor fine particles 4.

The sensitizing dye, which has lost electrons, receives electrons from ions in the electrolyte layer 5 (a carrier moving layer).

The molecule which has transferred electrons receives electrons again from the transparent conducting layer 3 constituting the counter electrode 12. In this way current flows between the two electrodes.

The foregoing embodiment has been described assuming that the photoelectric converter 1 is a dye-sensitized solar cell. The present invention is applicable to solar cells of other types than dye-sensitized ones and also to photoelectric converting elements other than solar cells.

The present invention will be modified as desired without departing from the scope thereof.

### EXAMPLES

Samples of photoelectric converters differing in structure as shown below were prepared.

### Example 1

The first step was preparation of TiO₂ paste for the layer of semiconductor fine particles 4.

The TiO₂ paste was prepared as follows with reference to “Modern Technology of Dye-sensitized Solar Cells” issued by C.M.C.

Titanium isopropoxide (125 mL) was slowly added dropwise with stirring to 750 mL of aqueous solution of 0.1 M nitric acid at room temperature. Stirring was continued for 8 hours in a thermostat at 80° C. There was obtained a semiopaque turbid sol solution. After cooling to room temperature, this sol solution was filtered through a glass filter. Thus there was obtained 700 mL of sol solution.

The sol solution underwent hydrothermal treatment in an autoclave at 220° C. for 12 hours. The treated solution further underwent ultrasonic treatment for 1 hour to ensure dispersion. The resulting solution was concentrated by an evaporator at 40° C., so that the content of TiO₂ in the concentrated solution increased to 20 wt %.

The concentrated sol solution was incorporated with polyethylene glycol having a molecular weight of 500,000 (in an amount of 20 wt % based on the amount of TiO₂) and anatase TiO₂ having a particle diameter of 200 nm (in an amount of 30 wt % based on the amount of TiO₂). The resulting mixture was evenly mixed using a stirring deaerator. Thus there was obtained a thickened TiO₂ paste.

The TiO₂ paste was applied to a fluorine-doped conducting glass substrate (having a sheet resistance of 10Ω/□) by blade coating method, so that there was obtained a coating film measuring 5 mm by 5 mm and 200 μm thick. The coating film was fired at 450° C. for 30 minutes so that TiO₂ particles bonded to the conducting glass.

The resulting TO₂ layer underwent hydrothermal treatment with an aqueous solution of 20 M KOH at 110° C. for 1 hour in a Teflon-lined stainless steel autoclave. The TiO₂ layer, which had undergone hydrothermal treatment, was given dropwise an aqueous solution of 0.1 M TiCl₄ and then allowed to stand at room temperature for 15 hours. After cleaning, the TiO₂ layer was fired at 450° C. for 30 minutes. The resulting TiO₂ product was cleaned of impurities and then irradiated with UV light for 30 minutes (by using a UV irradiating apparatus) for the purpose of increasing its activity.

The next step is to prepare the semiconductor electrode by causing the layer of semiconductor fine particles to support a sensitizing dye.

This step was accomplished by dipping at 80° C. for 24 hours in a solution of a 1:1 (by volume) mixed solvent of tert-butyl alcohol and acetonitrile containing 0.3 mM of cis-bis(isothiocyanate)-N,N-bis(2,2′-pyridyl-4,4′-carboxylic acid) ruthenium (II) ditetrabutylammonium salt and 20 mM of deoxycholic acid.

The resulting semiconductor electrode was washed with acetonitrile solution containing 50 vol % of 4-tert-butylpyridine and then with acetonitrile alone. The washed semiconductor electrode was dried in a dark place.

The counter electrode was prepared in the following manner.

First, a fluorine-doped conducting glass substrate (having a sheet resistance of 10Ω/□) was coated by sputtering sequentially with chromium (50 nm thick) and platinum (100 nm thick). The glass substrate has a previously formed inlet port (0.5 mm). The coating layer was further coated (by spray coating) with an isopropyl alcohol (IPA) solution of chloroplatinic acid, followed by heating at 385° C. for 15 minutes.

The photoelectric converter was prepared in the following manner from the semiconductor electrode and the counter electrode prepared as mentioned above.

The semiconductor electrode and the counter electrode (with the TiO₂ layer and the platinum layer facing each other) were bonded together at their periphery with the help of an ionomer resin film (30 μm thick) and silicone adhesive such that a space is left between them.

An electrolyte composition was prepared from 3 g of methoxyacetonitrile (as a solvent), 0.04 g of sodium iodide (NaI), 0.479 g of 1-propyl-2,3-dimethylimidazolium iodide, 0.0381 g of iodine (I₂), and 0.2 g of 4-tert-butylpyridine.

The electrolyte composition was introduced into the space between the two electrodes by using a liquid pump, followed by evacuation for defoaming. The inlet port was sealed with an ionomer resin film, silicone adhesive, and glass plate. Thus there was obtained the desired photoelectric converter.

### Examples 2 and 3

The same procedure as in Example 1 was repeated to prepare the photoelectric converter except that the aqueous solution shown in Table 1 below was used for hydrothermal treatment of the TiO₂ film constituting the layer of semiconductor fine particles.

### Examples 4 to 6

The same procedure as in Example 1 was repeated to prepare the photoelectric converter except that hydrothermal treatment was performed on the TiO₂ film constituting the layer of semiconductor fine particles under the condition (duration of treatment) shown in Table 1 below.

### Examples 7 to 9

The same procedure as in Example 1 was repeated to prepare the photoelectric converter except that hydrothermal treatment was performed on the TiO₂ film constituting the layer of semiconductor fine particles under the condition (temperature of treatment) shown in Table 1 below.

### Examples 10 to 14

The same procedure as in Example 1 was repeated to prepare the photoelectric converter except that hydrothermal treatment was performed on the TiO₂ film constituting the layer of semiconductor fine particles under the condition (concentration and pH of aqueous solution) shown in Table 1 below.

### Comparative Example 1

The same procedure as in Example 1 was repeated to prepare the photoelectric converter except that hydrothermal treatment was not performed on the TiO₂ film constituting the layer of semiconductor fine particles.

### Comparative Example 2

The same procedure as in Example 1 was repeated to prepare the photoelectric converter except that hydrothermal treatment with pure water was performed on the TiO₂ film constituting the layer of semiconductor fine particles.

TABLE 1

| | | | | | | Duration | |
|---|---|---|---|---|---|---|---|
| | | Concen- | | | Temperature | of | |
| | Additive | tration | | pH | of treatment | treatment | |
| Example 1 | KOH | 20 | M | >14 | 110° C. | 1 | hour |
| Example 2 | LiOH | 20 | M | >14 | 110° C. | 1 | hour |
| Example 3 | NaOH | 20 | M | >14 | 110° C. | 1 | hour |
| Example 4 | KOH | 20 | M | >14 | 110° C. | 15 | min |
| Example 5 | KOH | 20 | M | >14 | 110° C. | 3 | hour |
| Example 6 | KOH | 20 | M | >14 | 110° C. | 6 | hour |
| Example 7 | KOH | 20 | M | >14 | 80° C. | 1 | hour |
| Example 8 | KOH | 20 | M | >14 | 150° C. | 1 | hour |
| Example 9 | KOH | 20 | M | >14 | 200° C. | 1 | hour |
| Example 10 | KOH | 0.1 | M | 13.0 | 110° C. | 1 | hour |
| Example 11 | KOH | 1 | M | 14.0 | 110° C. | 1 | hour |
| Example 12 | KOH | 10 | M | >14 | 110° C. | 1 | hour |
| Example 13 | KOH | 0.0001 | M | 10 | 110° C. | 1 | hour |
| Example 14 | KOH | 0.01 | M | 12 | 110° C. | 1 | hour |

| Comparative | — | — | — | — | — | |
|---|---|---|---|---|---|---|
| Example 1 | | | | | | |
| Comparative | — | — | 6.7 | 110° C. | 1 | hour |
| Example 2 | | | | | | |

The photoelectric converters prepared in Examples 1 to 14 and Comparative Examples 1 and 2 were examined for the semiconductor electrode to measure the specific surface area of the layer of semiconductor fine particles.

They were also tested for the short-circuit current density and the photoelectric conversion efficiency by irradiation with artificial sunlight (AM1.5, 100 mW/cm²). The results are shown in Table 2 below.

TABLE 2

| | | | Photoelectric |
|---|---|---|---|
| | Specific surface | Short-circuit current | conversion |
| | area (m²/g) | density (mA/cm²) | efficiency (%) |
| Example 1 | 233 | 16.3 | 7.7 |
| Example 2 | 151 | 15.0 | 7.0 |
| Example 3 | 175 | 15.5 | 7.2 |
| Example 4 | 125 | 14.9 | 6.5 |
| Example 5 | 292 | 16.2 | 7.5 |
| Example 6 | 319 | 16.4 | 7.5 |
| Example 7 | 203 | 15.7 | 7.0 |
| Example 8 | 294 | 16.1 | 7.6 |
| Example 9 | 351 | 15.8 | 7.2 |
| Example 10 | 52 | 14.3 | 6.5 |
| Example 11 | 75 | 14.3 | 6.5 |
| Example 12 | 195 | 15.5 | 7.0 |
| Example 13 | 41 | 14.2 | 6.0 |
| Example 14 | 42 | 14.1 | 6.2 |
| Comparative | 40 | 14.2 | 6.1 |
| Example 1 | | | |
| Comparative | 40 | 14.0 | 6.0 |
| Example 2 | | | |

It is noted from Table 2 that the samples in Examples 1 to 12 (with hydrothermal treatment with an alkaline aqueous solution) as compared with the sample in Comparative Example 1 (without hydrothermal treatment) have a larger specific surface area of the layer of semiconductor fine particles. The larger specific surface area permits an increase in the amount of sensitizing dye to be supported, which in turn leads to a increased short-circuit current density and a greatly increased photoelectric conversion efficiency.

Hydrothermal treatment with pure water in Comparative Example 2 does not increase the specific surface area of the layer of semiconductor fine particles.

The results in Examples 1 to 3 suggest that an aqueous solution of KOH is most effective for hydrothermal treatment.

The results in Examples 4 to 6 suggest that prolonged hydrothermal treatment is effective in increasing the specific surface area of the layer of semiconductor fine particles.

The results in Examples 7 to 9 suggest that hydrothermal treatment at a high temperature is effective in increasing the specific surface area of the layer of semiconductor fine particles.

The results in Examples 10 to 14 suggest that hydrothermal treatment varies in its effect (of increasing the specific surface area of the layer of semiconductor fine particles) depending on conditions. It produces its desired effect if the aqueous solution has pH 10 or above. It produces its desired effect if the treatment is carried out at a high temperature or for a long time even though the aqueous solution has a low pH value.

1. A photoelectric converter of the type having a transparent substrate, at least one semiconductor electrode formed thereon which comprises a layer of semiconductor fine particles, a counter electrode, and an electrolyte layer held between said semiconductor electrode and said counter electrode,
wherein said layer of semiconductor fine particles is prepared by forming a film from semiconductor fine particles on said transparent substrate and subjecting the film to hydrothermal treatment in an environment of pH 10 or higher, so that the semiconductor fine particles have an increased specific surface area.

2. The photoelectric converter as defined in claim 1, wherein the hydrothermal treatment is carried out in an aqueous solution containing at least one compound selected from a group consisting of KOH, NaOH, LiOH, RbOH, Ca(OH)₂, Mg(OH)₂, Sr(OH)₂, Ba(OH)₂, Al(OH)₃, Fe(OH)₃, Cu(OH)₂, ammonium compounds, and pyridinium compounds.

3. The photoelectric converter as defined in claim 1, wherein the material constituting the layer of semiconductor fine particles contains at least one compound selected from a group consisting of TiO₂, ZnO, WO₃, Nb₂O₅, TiSrO₃, and SnO₂.

4. A semiconductor electrode composed of a transparent substrate and a layer of semiconductor fine particles formed thereon, wherein said layer of semiconductor fine particles undergoes hydrothermal treatment after the layer of semiconductor fine particles has been formed on the transparent substrate so that their specific surface area is increased.
